(19) United States
(12) Patent Application Publication
(10) Pub. No.: US 2006/0273713 A1
(43) Pub. Date: Dec. 7, 2006

(54) Process for making an organic light-emitting device

(75) Inventors: Rajesh V. Mehta, Rochester, NY (US); Ramesh Jagannathan, Rochester, NY (US); Bradley M. Houghtaling, Rochester, NY (US); Robert Link, Webster, NY (US); Kelly S. Robinson, Fairport, NY (US); Ross A. Sprout, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/143,167

(22) Filed: Jun. 2, 2005

(51) Int. Cl. H01L 51/50; H01L 51/56

(52) U.S. Cl. 313/504; 428/917; 428/690; 427/66

(57) ABSTRACT

In accordance with one embodiment, the present invention is directed towards a process for forming an organic electroluminescent device comprising depositing on a substrate at least first and second electrode layers and an organic EL element comprising one or more organic material layers between the first and second electrode layers, wherein at least one organic material layer of the EL element is deposited by providing a continuous stream of amorphous solid particles of organic material suspended in at least one carrier gas, the solid particles having a volume-weighted mean particle diameter of less than 500 nm, and depositing particles of the organic material to form a thin uniform layer of the organic material on the substrate surface.

### CROSS-REFERENCE TO RELATED APPLICATION

Reference is made to concurrently filed, co-pending application U.S. Ser. No. ______ (Kodak Docket No. 88603) by Rajesh V. Mehta et al entitled “Deposition of Uniform Layer of Desired Material” filed simultaneously herewith, the disclosure of which is incorporated by reference herein.

### FIELD OF INVENTION

This invention relates to organic electroluminescent (EL) devices. More specifically, this invention relates to a process for deposition of organic material layers in such devices.

### BACKGROUND OF THE INVENTION

Organic electroluminescent (EL) devices have been known for over two decades, and have many desirable features such as low driving voltage, high luminance, wide-angle viewing and capability for full-color flat emission displays. Tang et al. described a multilayer organic light emitting device (OLED) in their U.S. Pat. Nos. 4,769,292 and 4,885,211. However, despite these advantages, the extent of OLED penetration into the display marketplace has been limited by manufacturing difficulty and high cost. In simplest form, an organic EL device is comprised of an anode for hole injection, a cathode for electron injection, and an organic medium sandwiched between these electrodes to support charge recombination that yields emission of light. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, Vol. 30, pp. 322-334, 1969; and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often >100V.

More recent organic EL devices include an organic EL element consisting of extremely thin layers (e.g. <1.0 μm) between the anode and the cathode. Herein, the term “organic EL element” encompasses the layers between the anode and cathode electrodes. Reducing the thickness lowered the resistance of the organic layer and has enabled devices that operate at much lower voltage. In a basic two-layer EL device structure, described first in U.S. Pat. No. 4,356,429, one organic layer of the EL element adjacent to the anode is specifically chosen to transport holes, therefore, it is referred to as the hole-transporting layer, and the other organic layer is specifically chosen to transport electrons, referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by Tang et al [J. Applied Physics, Vol. 65, Pages 3610-3616, 1989]. The light-emitting layer commonly consists of a host material doped with a guest material. Still further, there has been proposed in U.S. Pat. No. 4,769,292 a four-layer EL element comprising a hole-injecting layer (HIL), a hole-transporting layer (HTL), a light-emitting layer (LEL) and an electron transport/injection layer (ETL). These structures have resulted in improved device efficiency.

Physical vapor deposition in a vacuum environment using the principle of sublimation is the dominant way of depositing thin organic material films as used in small molecule OLED devices. Such methods are well known, for example, Barr in U.S. Pat. No. 2,447,789 and Tanabe et al. in EP 0 982 411. The organic materials used in the manufacture of OLED devices are often subject to degradation when maintained at or near the desired rate-dependent vaporization temperature for extended periods of time. Exposure of sensitive organic materials to higher temperatures can cause changes in the structure of the molecules and associated changes in material properties.

To overcome the thermal sensitivity of these materials, only small quantities of organic materials have been loaded in sources, and they are heated as little as possible. In this manner, the material is consumed before it has reached the temperature exposure threshold to cause significant degradation. The limitations with this practice are that the available vaporization rate is very low due to the limitation on heater temperature, and the operation time of the source is very short due to the small quantity of material present in the source. The low deposition rate and frequent source recharging place substantial limitations on the throughput of OLED manufacturing facilities.

A secondary consequence of heating the entire organic material charge to roughly the same temperature is that it is impractical to mix additional organic materials, such as dopants, with a host material unless the vaporization behavior and vapor pressure of the dopant is very close to that of the host material. This is generally not the case and, as a result, prior art devices frequently require the use of separate sources to co-deposit host and dopant materials.

The organic materials used in OLED devices typically may have a highly non-linear vaporization rate dependence on source temperature. A small change in source temperature may lead to a very large change in vaporization rate. Despite this, prior-art devices employ source temperature as the only way to control vaporization rate. To achieve good temperature control, prior-art deposition sources typically utilize heating structures whose solid volume is much larger than the organic charge volume, composed of high thermal-conductivity materials that are well insulated. The high thermal conductivity insures good temperature uniformity through the structure, and the large thermal mass helps to maintain the temperature within a critically small range by reducing temperature fluctuations. These measures have the desired effect on steady-state vaporization rate stability but have a detrimental effect at start-up. It is common that these devices must operate for many hours at start-up before steady-state thermal equilibrium and hence a steady vaporization rate is achieved.

In U.S. Pat. No. 5,554,220 Forrest et al. disclose a method for vaporizing organic materials and organic precursors and delivering them to a deposition vessel wherein the substrate is situated while delivery of the vapors generated from solids or liquids is accomplished by use of carrier gases. The process is typically operated at several torr of pressure unlike earlier high vacuum techniques used to deposit ultra-thin layers of organic materials (U.S. Pat. No. 5,315,129). However, when it is necessary to uniformly co-deposit one or more dopants along with an EL material, then one must revert back to high vacuum techniques to ensure spatial concentration uniformity in the deposited layer.

In subsequent refinements of the technique, Forrest et al. (U.S. Pat. No. 6,337,102 B1) locate multiple substrates within a suitably large reactor vessel, and the vapors carried thereto mix and react or condense on the substrate. Another embodiment of their invention is directed towards applications involving coating of large area substrates and putting several such deposition processes in serial fashion with one another. For this embodiment, Forrest et al. disclose the use of a gas curtain fed by a gas manifold (defined in the disclosure as “hollow tubes having a line of holes”) in order to form a continuous line of depositing material perpendicular to the direction of substrate travel.

The Organic Vapor Phase Deposition approach to vapor delivery as disclosed by Forrest et al. can be characterized as “carrier gas assisted, remote vapor deposition” wherein a material is converted to vapor in an apparatus external to the deposition zone and more likely external to the deposition chamber. Organic vapors, alone or in combination with carrier gases are conveyed into the deposition chamber and ultimately to the substrate surface. Great care must be taken using this approach to avoid unwanted condensation in the delivery lines by use of appropriate heating methods. This problem becomes even more critical when contemplating the use of inorganic materials that vaporize to the desired extent at substantially higher temperatures. Furthermore, the delivery of the vaporized material for coating large areas uniformly requires the use of gas manifolds. No mention of the requirements for such a gas manifold is made by Forrest et al.

As can be appreciated from the disclosure of Forrest et al., one skilled in the art would expect to have difficulty providing uniform films from an elongated source in which the material is vaporized along the length of a deposition source within the deposition zone. Clearly, the technique suffers from several limitations as noted above.

The central limitation of chemical vapor deposition and organic vapor phase deposition is that the desired film layer is essentially assembled on a molecule-by-molecule basis and, therefore, the rate of film thickness growth is inherently slow. Deposition rates are typically on the order of a few tens or at most a hundred angstroms/sec at best. This molecular assembly route is dictated by the need in OLED devices to have thin, continuous layers in which the charge carrier mobilities are not adversely affected by unwanted trapping events. This ensures that the maximum flux of carriers recombine, intentionally, in the emissive layer and do not hang up in the hole or electron-transporting layers. Assembly by clusters or agglomerated particles, which would lead to much higher film formation rates, would introduce stacking faults or crystalline dislocations and other imperfections that would function as trapping centers and degrade carrier mobility, as is pointed out in U.S. Pat. No. 5,315,129. Another limitation of these techniques is that a significant fraction of the manufacturing cycle time is devoted to achieving stable operating conditions of material supply or else attainment of vacuum conditions.

The organic materials that are employed as EL layers may also be deposited from a fluid, for example, from a solvent with an optional binder to improve film formation. If the material is a polymer, solvent deposition is useful but other methods can be used, such as sputtering or thermal transfer from a donor sheet. The material to be deposited can be first coated onto a donor sheet and then sublimed in closer proximity to the substrate. Layers with a mixture of materials can be pre-mixed and solvent coated or else sublimed from a single donor sheet. Patterned deposition can be achieved using shadow masks, integral shadow masks (U.S. Pat. No. 5,294,870), spatially defined thermal dye transfer from a donor sheet (U.S. Pat. Nos. 5,688,551, 5,851,709 and 6,066,357) and inkjet method (U.S. Pat. No. 6,066,357). Solvent coating and thermal donor deposition techniques suffer from the limitations of line width resolution, device through put and the issue of evaporated solvent handling.

Recently, compressed CO₂ that is maintained in a supercritical state has been suggested as a medium to generate nanoparticles of organic matter that when deposited as a uniform layer, has utility in an OLED-type device. Supercritical fluids have unique properties, since they combine liquid-like solvent power with gas-like transport properties. They have a large compressibility compared to ideal gases. Therefore, a small change in temperature or pressure near the critical values will result in large changes in the fluid's density and hence its solvent power. These characteristics can be utilized to provide highly controllable solvent properties. Carbon dioxide is the most widely used supercritical fluid, due to the favorable critical parameters (Tc=31.1° C., Pc=73.8 bar), cost and non-toxicity.

Two basic principles for precipitating nanoparticles with supercritical fluids have been developed, Rapid Expansion of Supercritical Solutions (RESS) and Supercritical Anti-solvent (SAS) or Gas Anti-solvent (GAS) precipitation. In RESS type processes the sensitivity of solvent power of a supercritical fluid to small changes in pressure is used to trigger a mechanical precipitation of solute particles from the supercritical fluid.

In general, a process is considered a RESS process when the functional material is dissolved or dispersed in a supercritical fluid or a mixture of supercritical fluid and a liquid solvent, or a mixture of a supercritical fluid and surfactant, or a combination of these, which is then rapidly expanded to cause simultaneous precipitation of the functional material. Tom, J. W. and Debenedetti, P. B. discuss RESS techniques in “Particle Formation with Supercritical Fluids--a Review,” J. Aerosol. Sci. (1991) 22:555-58.

RESS type processes are known to produce very small (e.g., less than 100 nanometer) molecular clusters, ion pairs, or dispersed individual molecules under certain conditions. However, RESS is not suitable for use with many substances, in view of the requirement for solubility in the supercritical fluid. RESS processes are also most typically batch processes, and share similar through put limitations as sublimation techniques. These considerations not withstanding, U.S. Pat. No. 6,695,980 entitled “A Compressed Fluid Formulation Containing Electroluminescent Material” by Sadasivan Sunderrajan et al discloses an imaging composition comprising a mixture of a compressed fluid and a functional electroluminescent material dissolved or dispersed therein and, optionally present a surfactant and or dopant molecule which may be used to make an OLED device, where the process employed in a RESS type process. US2004/0109951, US2004/0108510, US2004/0110866, US2004/0110028, US2004/0265478 and US2004/0265622 also describe the use of the RESS type processes for EL device component layers (including, e.g., both hole and electron injecting and transporting layers). Copending, commonly assigned U.S. Ser. No. 10/744,539 (Docket 85281) also describes use of a RESS type process with examples employing materials that may be useful in EL devices for formation of thin films from organic nanocrystals, where the thin films which exhibit a long range periodicity in the arrangement of the organic nanocrystals in a self assembled superlattice structure.

Copending, commonly-assigned U.S. Ser. No. 10/805,980 (Docket 87180) discloses a method for vaporizing organic materials onto a surface, to form a film comprising: providing a quantity of organic material in a fluidized powdered form; metering the powdered organic material and directing a stream of such fluidized powder onto a permeable member; heating the permeable member so that as the stream of fluidized powder passes through it flash vaporizes; collecting the vaporized organic material and passing it through manifolds to direct it onto a surface to form a film. In another embodiment, the organic material is provided in a fluidized powdered form by evaporation or rapid expansion of a solution of the organic material in a supercritical solvent, and then flash vaporized. This method is essentially a PVD process and relies critically on controlled metering of fluidized powder, its flash vaporization, and controlled deposition of vapor under vacuum, e.g. a pressure of 1 torr or less, onto a substrate to form a film. Also, the applicability of such a process where the substrate is at or near ambient atmospheric pressures is unknown but likely to be problematic: depending on the vaporization rate, it may be difficult, if not impossible, to achieve flash vaporization, and once formed, vapor may transform into particles in its flight to the substrate and that may have detrimental effect on the performance of the film in the final device.

Most commonly practiced SAS type processes use a solution or suspension of the substance in a suitable carrier fluid, usually an organic solvent, and contact it with supercritical fluid, usually carbon dioxide, under controlled conditions of pressure, temperature, and rates of addition through capillary nozzles. Their use is extensively documented; see for instance “Strategies for Particle Design using Supercritical Fluid Technologies”, Pharmaceutical Science & Technology Today, 2 (11), 430440 (1999); “Supercritical Antisolvent Precipitation of Micro- and Nano-Particles”, J. of Supercritical Fluids, 15, 1-21 (1999); and “Particle Design Using Supercritical Fluids: Literature and Patent Survey”, J. of Supercritical Fluids, 20 179-219 (2001). Unlike RESS processes, SAS processes can advantageously be used to precipitate particles of a substance that are insoluble in the supercritical fluid, provided that the supercritical fluid is miscible with the liquid in which the substance is dissolved. The SAS process also lends itself readily to a continuous rather than batch mode of operation.

Typically SAS processes produce particles in micron size range although recent advances have shown that nanometer sized particles are also possible. For example, commonly assigned, copending U.S. Ser. No. 10/814,354 (Docket 86430) discloses a SAS process that produces molecular clusters that are a few nanometers in diameter and also feature very narrow size-frequency distributions. Commonly assigned, copending U.S. Ser. No. 10/815,026 (Docket 87485) discloses that the particles (colorants, dyes, pharmaceutical compounds or organic electroluminescent materials) produced by the process disclosed in U.S. Ser. No. 10/814,354 can be directed to a receiver to form thin films or coatings in a steady state continuous manner. Coating formation can be greatly assisted by corona, or injection or tribo charging processes. However, the use of a thermal treatment for the nanoparticles for flash evaporation is not disclosed in the aforementioned application.

Despite the advances made in the arts of physical vapor deposition, organic vapor phase deposition, layer deposition by rapid expansion of a supercritical solvent (RESS), and ink jet printing, there is a continuing need to improve methods for OLED device manufacture.

### SUMMARY OF THE INVENTION

In accordance with one embodiment, the present invention is directed towards a process for forming an organic electroluminescent device comprising depositing on a substrate at least first and second electrode layers and an organic EL element comprising one or more organic material layers between the first and second electrode layers, wherein at least one organic material layer of the EL element is deposited by

(i) providing a continuous stream of amorphous solid particles of organic material suspended in at least one carrier gas, the solid particles having a volume-weighted mean particle diameter of less than 500 nm, at an average stream temperature below the glass transition temperature of the solid particles of organic material,

(ii) passing the stream provided in (i) into a heating zone, and heating the stream in the heating zone to elevate the average stream temperature to above the glass transition temperature of the solid particles of organic material, wherein no substantial chemical transformation of the organic material occurs due to heating of the organic material,

(iii) exhausting the heated stream from the heating zone through at least one distributing passage, at a rate substantially equal to its rate of addition to the heating zone in step (ii), wherein the carrier gas does not undergo a thermodynamic phase change upon passage through the heating zone and distribution passage, and

(iv) maintaining the substrate at a temperature below the temperature of the heated stream while exposing the substrate to the exhausted flow of the heated stream to deposit particles of the organic material to form a thin uniform layer of the organic material on the substrate surface.

### ADVANTAGEOUS EFFECT OF THE INVENTION

The method of OLED device manufacture by the present invention provides a process to continuously deposit multicomponent, organic, EL materials on a substrate, that does not require high temperature nor high vacuum, while improving the control and spatial homogeneity of the deposition. This results in improved OLED device performance while simultaneously achieving a higher degree of spatial uniformity of luminescent dopants. In accordance with various embodiments of the invention, effective organic electroluminescent devices may be manufactured with layers advantageously deposited at atmospheric or near atmospheric pressure. In accordance with further various embodiments, organic electroluminescent devices may be provided with at least one layer that exhibits long-range order and short-range disorder. In accordance with still further various embodiments, at least one layer in an organic electroluminescent device may be deposited at atmospheric pressure, where the deposited layer exhibits the necessary interfacial properties for efficient device performance.

### BRIEF DESCRIPTION OF THE DRAWINGS

FIG. 1 shows a cross-section of an OLED device.

### DETAILED DESCRIPTION OF THE INVENTION

Materials in their solid state are known to have different degrees of order in the arrangement of its constituents. Highly ordered solids are crystalline and those crystals may have a variety of sizes and shapes. Crystalline solids have a sharp melting point. Highly disordered solids are amorphous. They are commonly called glassy solids. They have molecular structure of liquids but have properties (e.g., viscosity, thermal expansion, specific heat etc.) like solids. In a sense, they are cooled liquids where molecular motion of liquid is brought to a halt due to cooling. When amorphous materials are heated, their properties start becoming liquid-like beyond a certain temperature. This is commonly called the glass transition temperature, Tg. With further increase in temperature over a range, the material increasingly becomes more liquid-like, eventually melting fully at its melting point. In this state between the glass transition temperature and the melting temperature, solids behave like liquids with very high viscosity.

Organic electroluminescent devices may be formed by depositing on a substrate at least first and second electrode layers and an organic EL element comprising one or more organic material layers between the first and second electrode layers. The invention is applicable to the preparation of organic EL devices comprising coatings of a wide variety of organic materials. Representative organic materials useful in formation of organic EL element organic material layers are more fully described below. In accordance with the invention, amorphous solid particles of such organic materials may be deposited to form at least one organic material layer of the EL element in the form of a uniform thin film by suspended such amorphous solid particles in a carrier gas, heating them above their Tg, and directing the flow to a substrate to be coated that is at a temperature lower than the heated flow. The volume averaged particle diameter for such particles employed in the process of the invention is below 500 nm, more preferably below 100 nm, most preferably below 10 nm. Lower particle size is desired for higher coating surface smoothness and ability to coat higher quality films where film thickness is, e.g., less than 10 micrometer, preferably below 1 micrometer, and more preferably below 0.5 micrometer. Also, it is known that particles begin to melt at their surfaces at temperature lower than its bulk (see, for example, P. Tibbits et al. in J. Vac. Sci. Technol. (1991)A9(3):1937). A similar phenomenon may also lower the effective glass transition temperature for nano-scale particles employed in the present invention, enabling the process to be effective at lower heating temperatures than may be required for processes employing larger size particles in coating applications. Also, the melting behavior of the particle is significantly affected by the contacting substrate (see for example, V. Storozhev in Surface Science (1998) 397:170-178).

The carrier gas employed in such process may be air, CO₂, CO, inert gases like N₂, He, Ar, Xe, or suitable mixture thereof. In addition, a wide variety of compressed fluids known in the art, and in particular supercritical fluids (e.g., CO₂, NH₃, H₂O, N₂O, ethane etc.), may in their expanded state, be considered for such a selection, with supercritical CO₂ being generally preferred. Similarly, a wide variety of commonly used carrier solvents (e.g., ethanol, methanol, water, methylene chloride, acetone, toluene, dimethyl formamide, tetrahydrofuran, etc.) may also be present as minor components. Since any such solvents are intended to be in the gaseous state during the deposition of the desired organic material, solvents with higher volatility at lower temperatures are more desired.

Continuous sources of desired organic material particle laden gas flow which may be employed in this invention include, without limitations, flow exiting from any suitably designed nozzle that mixes the carrier gas with the solid particles, for example, spray nozzles useful in thermal spray or powder coating applications; modules described in U.S. Pat. No. 6,511,149 for combining the propellant gas and marking material in a ballistic aerosol marking system; and outlet of an aerosol generator or concentrator. In accordance with a preferred embodiment, the stream of particles of a desired organic material substance suspended in a carrier gas may be obtained from the final expansion nozzle of a supercritical fluid based particle formation system, such as a rapid expansion of supercritical solution (RESS) type system or a supercritical anti-solvent (SAS) type system, and more preferably from a SAS type system such as described, for example, in commonly assigned U.S. Ser. No. 10/815,026 (Docket 87485) and U.S. Ser. No. 10/814,354 (Docket 86430), the disclosures of which are incorporated by reference herein.

When employing a SAS type process, the stream may be prepared under essentially steady state conditions by precipitation of the desired substance to be deposited from a solution upon contact with a compressed fluid antisolvent in a particle formation vessel and exhaustion of the particle and compressed fluid from the vessel through an expansion nozzle. As in known SAS type processes, solvents for use in such embodiment of the present invention may be selected based on ability to dissolve the desired material, miscibility with a compressed fluid antisolvent, toxicity, cost, and other factors. The solvent/solute solution is then contacted with a compressed fluid antisolvent in a particle formation vessel, the temperature and pressure in which are controlled, where the compressed fluid is selected based on its solubility with the solvent and relative insolubility of the desired particulate material (compared to its solubility in the solvent), so as to initiate precipitation of the solute from the solvent upon rapid extraction of the solvent into the compressed fluid. The functional material to be deposited has a relatively higher solubility in the carrier solvent than in the compressed fluid or than in the mixture of compressed fluid and the carrier solvent. This enables the creation of a high supersaturation zone in the vicinity of the introduction point where the solution of functional material in the carrier solvent is added into the particle formation vessel. A wide variety of compressed fluids known in the art, and in particular supercritical fluids (e.g., CO₂, NH₃, H₂O, N₂O, ethane etc.), may be considered in such a selection, with supercritical CO₂ being generally preferred. Similarly, a wide variety of commonly used carrier solvents (e.g., ethanol, methanol, water, methylene chloride, acetone, toluene, dimethyl formamide, tetrahydrofuran, etc.) may be considered. Since, eventually both the compressed fluid and the carrier solvent are intended to be in the gaseous state, carrier solvents with higher volatility at lower temperatures are more desired. The relative solubility of functional material can also be adjusted by appropriate choice of pressure and temperature in the particle formation vessel.

Feed materials should be adequately mixed with the vessel contents upon their introduction into the vessel, such that the carrier solvent and desired substance to be deposited contained therein are dispersed in the compressed fluid, allowing extraction of the solvent into the compressed fluid and precipitation of particles of the desired substance. This mixing may be accomplished by the velocity of the flow at the introduction point, or through the impingement of feeds on to another or on a surface, or through provision of additional energy through devices such as a rotary mixer, or through ultrasonic vibration. It is desirable that the entire content of the particle formation vessel is maintained as close to a uniform concentration of particles as possible. The spatial zone of non-uniformity near the feed introduction should also be minimized. Inadequate mixing process may lead to an inferior control of particle characteristics. Thus, feed introduction into a region of high agitation, and the maintenance of a generally well-mixed bulk region is preferred. Most preferably, the solvent/desired substance solution and compressed fluid antisolvent are contacted in a particle formation vessel by introducing feed streams of such components into a highly agitated zone of the particle formation vessel, such that the first solvent/solute feed stream is dispersed in the compressed fluid by action of a rotary agitator as described in copending, commonly assigned U.S. Ser. No. 10/814,354 (Docket 86430), the disclosure of which is also incorporated by reference herein. As described in such copending application, effective micro and meso mixing, and resulting intimate contact of the feed stream components, enabled by the introduction of the feed streams into the vessel within a distance of one impeller diameter from the surface of the impeller of the rotary agitator, enable precipitations of particles of the desired substance in the particle formation vessel with a volume-weighted average diameter of less than 100 nanometers, preferably less than 50 nanometers, and most preferably less than 10 nanometers. In addition, a narrow size-frequency distribution for the particles may be obtained. The measure of the volume-weighted size-frequency distribution, or coefficient of variation (mean diameter of the distribution divided by the standard deviation of the distribution), e.g., is typically 50% or less, with coefficients of variation of even less than 20% being enabled. The size-frequency distribution may therefore be monodisperse. Process conditions may be controlled in the particle formation vessel, and changed when desired, to vary particle size as desired. Preferred mixing apparatus which may be used in accordance with such embodiment includes rotary agitators of the type which have been previously disclosed for use in the photographic silver halide emulsion art for precipitating silver halide particles by reaction of simultaneously introduced silver and halide salt solution feed streams. Such rotary agitators may include, e.g., turbines, marine propellers, discs, and other mixing impellers known in the art (see, e.g., U.S. Pat. No. 3,415,650; U.S. Pat. No. 6,513,965, U.S. Pat. No. 6,422,736; U.S. Pat. No. 5,690,428, U.S. Pat. No. 5,334,359, U.S. Pat. No. 4,289,733; U.S. Pat. No. 5,096,690; U.S. Pat. No. 4,666,669, EP 1156875, WO-0160511). Mixing apparatus which may be employed in one particular embodiment of the invention also includes mixing devices of the type disclosed in Research Disclosure, Vol. 382, February 1996, Item 38213, as well as in U.S. Pat. No. 6,422,736, the disclosures of which are incorporated by reference.

Regardless of the particular source of desired particle laden gas flow employed, the pressure and temperature of the flow are preferably maintained such that any solvent is substantially in its gas or vapor state and simultaneously the particle temperature is below its Tg prior to passing through a subsequent heating means in accordance with the invention. While the source stream pressure can range from several atmospheres to very high vacuum, and the source stream flow velocity may range from being supersonic to subsonic, in accordance with preferred embodiments the invention is particular advantaged in enabling the effective coating of organic EL element layers at ambient atmosphereric or near atmospheric pressure and at subsonic flow velocities.

The flow stream is then heated by a heating means. The heating means may include all suitable heating devices, including, but without limitations, an electric heater; a heated wall heat exchanger; a packed bed heater; a microwave heater; a plasma flame; a laser beam; and an inert hot gas that is directly mixed. The pressure and temperature of the flow are preferably maintained such that any solvent is substantially in its gas or vapor state, while simultaneously heating the particle temperature to above its Tg at the outlet of the heating means. It is preferred that the particle temperature stays below a value that ensures no substantial chemical modification of the particles or the surrounding gaseous material occurs, however, so as to avoid any detrimental effect on the coatings made downstream. In preferred embodiments, the temperature of the stream is also maintained such that the suspended particles are below their melting point as they leave the heated zone. Depending on the specific heating means used, the residence time of the flow stream in the heated zone may range from minutes to nanoseconds.

The effluent from the heating means is then passed through a flow distribution means at a rate substantially equal to the rate of addition of the stream to the heating zone. The distribution means may include, without limitations, suitably designed single or multiple conduits; apertures; and slots, that are in direct communication with the heating means, so as to direct the flow of effluents onto the receiver in a desired manner. In accordance with the present invention, the carrier gas does not undergo a thermodynamic phase change upon passage through heating zone and distribution passage, and thus the heating employed is distinguished from heating of a supercritical fluid expansion valve. The distribution means may also include valves or shutters for controlled delivery of flow with time.

The organic EL device substrate to be coated is located downstream of the distribution means, preferably at a distance and temperature determined experimentally to achieve the desired material deposition efficiency and film quality. The substrate will be at a temperature below the temperature of the heated stream, and preferably below the glass transition temperature of the desired material particles. Regardless of the substrate temperature, the distance between the distribution means and the substrate surface should preferably be maintained such that excessive cooling of the heated stream does not occur to an extent such that the desired material particles are cooled to below their Tg prior to contacting the substrate to be coated. In preferred embodiments, the substrate is maintained within 5 cm of the outlet of the distribution means, more preferably within 3 cm, and most preferably within 1 cm. By requiring the temperature of the nanoparticles to be above the Tg of the functional material particles, and that of the substrate to be coated to be below such Tg, the particles' affinity to adhere to the substrate is enhanced. Thus, such embodiment of the invention facilitates the formation of a thin film once the nanoparticles of functional material arrive at the substrate to be coated.

Subject to the above-described requirements, flow exiting from the distribution means may be directly used for coating the functional material onto a receiver substrate that is at ambient temperature. More preferably, however, the deposition surface is actively cooled to keep it at a temperature lower than the impinging gas stream temperature. In case of multilayer organic EL element coatings, the deposition surface temperature should also be kept at or below the Tg of the material in the underlying layer to mitigate any adverse interfacial effects in the final composite EL element film structure. In particular, the temperature of the deposition surface may be controlled to enhance the adhesion between layers of dissimilar materials or improve cohesion among layers of similar materials. Active cooling may be achieved by keeping a conventional cooling platen in close thermal contact underneath the receiver surface or with a moving substrate, for example, a roll-to roll web coating surface, or combination thereof. Using a cold environmental gas that does not chemically interfere may also help achieve practical cooling rates. In one preferred embodiment, the deposition surface is kept at a temperature substantially below the Tg of the functional material and simultaneously above the boiling point of any component organic solvent present in the heated stream. Such conditions substantially mitigate the role of the solvent molecules in film formation.

Depending on the dominant deposition mechanism, it may be advantageous to maximize the spatial temperature gradient at the deposition surface for improved deposition efficiency. For example, such conditions are known to improve thermophoretic deposition of nanoparticles. The phenomenon of thermophoresis causes small particles to be driven away from a hot surface towards a cold one (see, for example, Zheng F. in Adv. in Coll. & Interface Sci. (2002) 97:253-276). Depending on the specific application, a temperature gradient of greater than 10 degree C./mm to greater than 10⁵ degree C./mm may be desired. In another preferred embodiment the deposited material may be cooled rapidly to essentially keep the deposited particles amorphous. Depending on the specific application, preferred cooling rate may range from greater than 10 degree C./sec to greater than 10⁶C./sec.

In a particular embodiment of the invention, the substrate to be coated may be moved in relation to the exhausted flow of the heated stream to form the thin uniform layer of the desired organic material. Such relative movement may be achieved, e.g., by employing a continuous moving substrate which passes through a deposition zone as the receiver surface, and/or by moving the flow distribution means relative to the receiver surface. It may also be advantageous to move the receiver surface in and out of the deposition zone at a desired rate to manage the interfacial temperature and temperature gradient at the deposition surface. The rate of movement can be determined beneficially by taking into account the gas flow, and the impingement geometry, and the ambient environment. Alternatively, a shutter type arrangement may be employed to provide multiple exposures of substrate to the deposition zone to build the desired coating or film thickness while maintaining the temperature in the desired range. Additional electromagnetic or electrostatic means may also be used to interact with the exhaust from the distributor means to deflect the flow of functional material to the coating surface and enhance the material deposition rate. This includes electrostatic techniques such as induction, corona charging, charge injection or tribo-charging.

The invention advantageously enables thin organic material film layers of an organic EL element to be deposited at ambient or near ambient (e.g., within 10 percent of ambient) conditions of pressure, with an average surface roughness of less than 10 nm, preferably less than 5 nm, and even more preferably less than 0.5 nm, where the average surface roughness value is calculated by WYCO NT1000 as the arithmetic average of the absolute values of the surface features from the mean plane. Additional flow means may also be similarly employed to either control the momentum, or temperature, of the deposition flow stream. The coating surface may also be either treated (uniformly or patterned) before or during deposition to enhance the particle deposition efficiency. For example, coating surface may be exposed to plasma or corona discharges to improve adhesion of depositing particles. Similarly, coating surfaces may be pre-patterned to have regions of relatively high or low conductivity (e.g., electrical, thermal, etc.), or regions of relatively high or low lyo- (e.g., hydro-, lipo-, oleo-, etc.) phobicity, or regions of relatively high or low permeability.

While organic material layers of an EL element deposited in accordance with the process of the present invention are formed from amorphous solid particles, in certain embodiment of the invention the resulting amorphous deposited organic material films obtained by the described process may exhibit long-range order while simultaneously exhibiting short-range disorder as demonstrated in the examples of concurrently filed, co-pending U.S. Ser. No. ______ (Docket 88603) incorporated by reference above.

An additional feature for web or continuous coating applications is containment of the solvent vapors and particles that are not coated. This may be achieved by an enclosure that houses the coating station. Alternatively, a curtain of inert gases can also provide a sealing interface. Such an arrangement allows a highly compact apparatus for such applications. In certain applications, it may be advantageous to have additional post-coating processing capabilities such as heating or exposing to specific atmosphere. Similarly, multiple coating applicators may also be sequenced to create suitable multi-layer film architectures. A further aspect of manufacturing scale processes is recycling of processing fluids. This entails separation of carrier solvent vapors from the exhaust stream through condensation, a process that may also be used to trap and re-dissolve uncoated particles. The exhaust stream then could be recompressed and recycled as compressed fluid.

General Organic EL Device Architecture

The present invention can be employed in the manufacture of OLED devices that may be structured in a wide variety of configurations These include very simple structures comprising a single anode, organic EL layer and cathode to more complex devices, such as passive matrix displays comprised of orthogonal arrays of anodes and cathodes to form pixels, and active-matrix displays where each pixel is controlled independently, for example, with thin film transistors (TFTs).

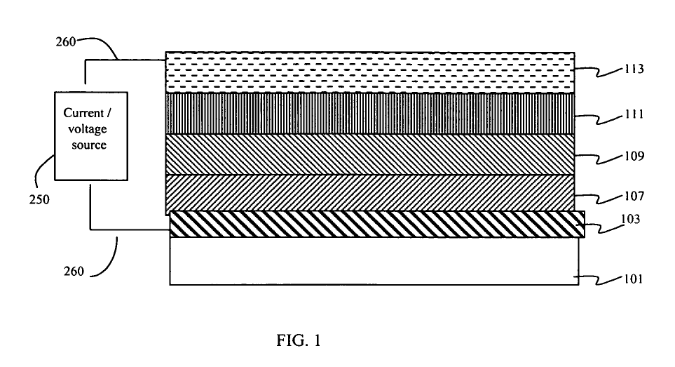

There are numerous configurations of the organic layers wherein the present invention can be successfully practiced. A typical structure is shown in FIG. 1 and is comprised of a substrate 101, an anode 103, a hole-injecting layer 105, a hole-transporting layer 107, a light-emitting layer 109, an electron-transporting layer 111, and a cathode 113. These layers are described in more detail below. Note that the substrate may alternatively be located adjacent to the cathode, or the substrate may actually constitute the anode or cathode. The organic layers between the anode and cathode are conveniently referred to as the organic EL element. The total combined thickness of the organic layers is preferably less than 500 nm.

The anode and cathode of the OLED are connected to a voltage/current source 250 through electrical conductors 260. The OLED is operated by applying a potential between the anode and cathode such that the anode is at a more positive potential than the cathode. Holes are injected into the organic EL element from the anode and electrons are injected into the organic EL element at the anode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

OLED devices are typically provided over a supporting substrate where either the cathode or anode can be in contact with the substrate. The substrate can have a simple or a complex structure with numerous layers, for example, a glass support with electronic elements such as TFT elements, planarizing layers, wiring layers, etc. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support is generally immaterial, and therefore can be light transmissive, light absorbing or light reflective. Substrates for use in this case include, but are not limited to, glass, plastic, semiconductor materials, silicon, ceramics, and circuit board materials. Of course it is necessary to provide in these device configurations a light-transparent top electrode.

Anode When EL emission is viewed through anode 103, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode electrode, the transmissive characteristics of anode are generally immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful to provide a hole-injecting layer 105 between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, fluorocarbon polymers as described in U.S. Pat. No. 6,127,004, U.S. Pat. No. 6,208,075 and U.S. Pat. No. 6,208,077, some aromatic amines, for example, m-MTDATA (4,4′,4″-tris[(3-methylphenyl)phenylamino]triphenylamine), and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1.

Hole-Transporting Layer (HTL)

The hole-transporting layer 107 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triaryl aamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
N,N,N′,N′-tetraphenyl-4,4′″-diamino-1,1′:4′,1″:4″,1′″-quaterphenyl
Bis(4-dimethylamino-2-methylphenyl)phenylmethane
1,4-bis[2-[4-[N,N-di(p-toly)amino]phenyl]vinyl]benzene (BDTAPVB)
N,N,N′,N′-Tetra-p-tolyl-4,4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl (NPB)
4,4′-Bis[N-(1-naphthyl)-N-(2-naphthyl)amino]biphenyl (TNB)
4,4′-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4′-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylanino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis{N-phenyl-N-[4-(1-naphthyl)-phenyl]amino}biphenyl
2,6-Bis[N,N-di(2-naphthyl)amino]fluorene
4,4′,4″-tris[(3-methylphenyl)phenylamino]triphenyl amine (MTDATA)
4,4′-Bis[N-(3-methylphenyl)-N-phenylamino]biphenyl (TPD)
   Another class of useful hole-transporting materials includes polycyclic aromatic compounds as described in EP 1 009 041. Some hole-injecting materials described in EP 0 891 121 A1 and EP 1 029 909 A1, can also make useful hole-transporting materials. In addition, polymeric hole-transporting materials can be used including poly(N-vinylcarbazole) (PVK), polythiophenes, polypyrrole, polyaniline, and copolymers including poly(3,4-ethylenedioxythiophene)/poly(4-styrenesulfonate) also called PEDOT/PSS.
   Light-Emitting Layer (LEL)

As more fully described in U.S. Pat. Nos. 4,769,292 and 5,935,721, each of the light-emitting layers (LEL) of an organic EL element include a luminescent fluorescent or phosphorescent material where electroluminescence is produced as a result of electron-hole pair recombination in this region. The light-emitting layer can be comprised of a single material, but more commonly contains a host material doped with a guest emitting material or materials where light emission comes primarily from the emitting materials and can be of any color. This guest emitting material is often referred to as a light emitting dopant. The host materials in the light-emitting layer can be an electron-transporting material, as defined below, a hole-transporting material, as defined above, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small non-polymeric molecules or polymeric materials including polyfluorenes and polyvinylarylenes (e.g., poly(p-phenylenevinylene), PPV). In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters (including materials that emit from a triplet excited state, i.e., so-called “triplet emitters”) it is also important that the host triplet energy level of the host be high enough to enable energy transfer from host to emitting material.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, U.S. Pat. No. 6,020,078, U.S. Pat. No. 6,475,648, U.S. Pat. No. 6,534,199, U.S. Pat. No. 6,661,023, US 20020127427A1, US20030198829A1, US20030203234A1, US20030224202A1, US20040001969A1.

Metal complexes of 8-hydroxyquinoline (oxine) and similar derivatives constitute one class of useful host compounds capable of supporting electroluminescence. Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo {f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Another class of useful host materials includes derivatives of anthracene, such as those described in U.S. Pat. No. 5,935,721, U.S. Pat. No. 5,972,247, U.S. Pat. No. 6,465,115, U.S. Pat. No. 6,534,199, U.S. Pat. No. 6,713,192, US 20020048687, US 20030072966 and WO 2004018587. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Desirable host materials are capable of forming a continuous film. The light-emitting layer may contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, derivatives of distryrylbenzene and distyrylbiphenyl, and carbostyryl compounds. Among derivatives of distyrylbenzene, particularly useful are those substituted with diarylamino groups, informally known as distyrylamines.

Suitable host materials for phosphorescent emitters (including materials that emit from a triplet excited state, i.e., so-called “triplet emitters”) should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2; 01/39234 A2; 01/93642 A1; 02/074015 A2; 02/15645 A1, and US 20020117662. Suitable hosts include certain aryl amines, triazoles, indoles and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

One class of useful phosphorescent materials is transition metal complexes having a triplet-excited state. For example, fac-tris(2-phenylpyridinato-N,C^{2′})iridium (III) (Ir(ppy)₃) strongly emits green light from a triplet excited state owing to the large spin-orbit coupling of the heavy atom and to the properties of the lowest excited state, which is a charge transfer state having a Laporte-allowed (orbital symmetry) transition to the ground state (K. A. King, P. J. Spellane, and R. J. Watts, J. Am. Chem. Soc. 1985, 107, 1431; M. G. Colombo, T. C. Brunold, T. Reidener, H. U. Gudel, M. Fortsch, and H.-B. Burgi, Inorg. Chem. 1994, 33, 545. Small-molecule, vacuum-deposited OLEDs having high efficiency have also been demonstrated with Ir(ppy)₃ as the phosphorescent material and 4,4′-N,N′-dicarbazole-biphenyl (CBP) as the host (M. A. Baldo, S. Lamansky, P. E. Burrows, M. E. Thompson, S. R. Forrest, Appl. Phys. Lett. 1999 4, 75, T. Tsutsui, M. -J. Yang, M. Yahiro, K. Nakamura, T. Watanabe, T. Tsuji, Y. Fukuda, T. Wakimoto, S. Miyaguchi, Jpn. J. AppL. Phys. 1999, 38, L1502). Another class of phosphorescent materials include compounds having interactions between atoms having d¹⁰ electron configuration, such as Au₂(dppm)Cl₂ (dppm=bis(diphenylphosphino)methane) (Y. Ma et al, Appl. Phys. Lett. 1998, 74, 1361). Still other examples of useful phosphorescent materials include coordination complexes of the trivalent lanthanides such as Tb³⁺ and Eu³⁺ (J. Kido et al, Appl. Phys. Lett. 1994, 65, 2124). While these latter phosphorescent compounds do not necessarily have triplet states as the lowest excited states, their optical transitions do involve a change in spin state of 1 and thereby can harvest the triplet excitons in OLED devices.

Although many phosphorescent Ir complexes have been described as useful in an EL device, Pt-based organometallic complexes have not been examined as extensively. Some Pt-based phosphorescent complexes include cyclometallated Pt (II) complexes, such as cis-bis(2-phenylpyridinato-N,C^{2′})platinum (II), cis-bis(2-(2′-thienyl)pyridinato-N,C^{3′})platinum (II), cis-bis(2-(2′-thienyl)quinolinato-N,C^{5′})platinum(II), (2-(4,6-difluorophenyl)pyridinato-N,C^{2′})platinum (II) acetylacetonate, or (2-phenylpyridinato-N,C^{2′})platinum (II) acetylacetonate. Pt (II) porphyrin complexes such as 2,3,7,8,12,13,17,18-octaethyl-21H,23H-porphineplatinum (II) are reported in U.S. Pat. No. 6,048,630 as useful phosphorescent materials in an electroluminescent device, although they did not give a very high luminance yield. Recently, C.-M. Che, W. Lu, and M. Chan reported organometallic light-emitting materials and devices based on (NˆNˆC) tridentate-cyclometalated Pt (II) acetylides (US 2002/0179885 A1 and references cited therein).

Other examples of useful phosphorescent materials that can be used in light-emitting layers of this invention include, but are not limited to, those described in WO 00/57676, WO 00/70655, WO 01/41512 A1, WO 02/15645 A1, US 2003/0017361 A1, WO 01/93642 A1, WO 01/39234 A2, U.S. Pat. No. 6,458,475 B1, WO 02/071813 A1, U.S. Pat. No. 6,573,651 B2, US 2002/0197511 A1, WO 02/074015 A2, U.S. Pat. No. 6,451,455 B1, US 2003/0072964 A1, US 2003/0068528 A1, U.S. Pat. No. 6,413,656 B1, U.S. Pat. No. 6,515,298 B2, U.S. Pat. No. 6,451,415 B1, U.S. Pat. No. 6,097,147, US 2003/0124381 A1, US 2003/0059646 A1, US 2003/0054198 A1, EP 1 239 526 A2, EP 1 238 981 A2, EP 1 244 155 A2, US 2002/0100906 A1, US 2003/0068526 A1, US 2003/0068535 A1, JP 2003073387A, JP 2003 073388A, US 2003/0141809 A1, US 2003/0040627 A1, JP 2003059667A, JP 2003073665A, US 2002/0121638 A1, and commonly assigned, copending U.S. Ser. No. 10/729,328 (Docket 87218).

Electron-Transporting Layer (ETL)

Preferred thin film-forming materials for use in forming the electron-transporting layer 111 of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

A metal-doped organic layer can be used as an electron-injecting layer. Such a layer contains an organic electron-transporting material and a low work-function metal (<4.0 eV). For example, Kido et al. reported in “Bright Organic Electroluminescent Devices Having a Metal-Doped Electron-Injecting Layer”, Applied Physics Letters, 73, 2866 (1998) and disclosed in U.S. Pat. No. 6,013,384 that an OLED can be fabricated containing a low work-function metal-doped electron-injecting layer adjacent to a cathode. Suitable metals for the metal-doped organic layer include alkali metals (e.g. lithium, sodium), alkaline earth metals (e.g. barium, magnesium), metals from the lanthanide group (e.g. lanthanum, neodymium, lutetium), or combinations thereof. The concentration of the low work-function metal in the metal-doped organic layer is in the range of from 0.1% to 30% by volume. Preferably, the concentration of the low work-function metal in the metal-doped organic layer is in the range of from 0.2% to 10% by volume. Preferably, the low work-function metal is provided in a mole ratio in a range of 1:1 with the organic electron transporting material.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,393. Cathode materials are typically deposited by evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, layers 109 and 111 can optionally be collapsed into a single layer that serves the function of supporting both light emission and electron transportation. It also known in the art that emitting dopants may be added to the hole-transporting layer, which may serve as a host. Multiple dopants may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. No. 5,683,823, U.S. Pat. No. 5,503,910, U.S. Pat. No. 5,405,709, and U.S. Pat. No. 5,283,182, US 20020186214, US 20020025419, US 20040009367, and U.S. Pat. No. 6,627,333.

Additional layers such as exciton, electron and hole-blocking layers as taught in the art may be employed in devices of this invention. Hole-blocking layers are commonly used to improve efficiency of phosphorescent emitter devices, for example, as in US 20020015859, WO 00/70655A2, WO 01/93642A1, US 20030068528 and US 20030175553 A1.

This invention may be used in so-called stacked device architecture, for example, as taught in U.S. Pat. No. 5,703,436, U.S. Pat. No. 6,337,492, and US 20030170491.

Encapsulation

Most OLED devices are sensitive to moisture or oxygen, or both, so they are commonly sealed in an inert atmosphere such as nitrogen or argon. In sealing an OLED device in an inert environment, a protective cover can be attached using an organic adhesive, a metal solder, or a low melting temperature glass. Commonly, a getter or desiccant is also provided within the sealed space. Useful getters and desiccants include, alkali and alkaline metals, alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters in functional relationship with the light emitting areas of the display. Filters, polarizers, and anti-glare or anti-reflection coatings can also be provided over a cover or as part of a cover.

The OLED device may have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length can be tuned by selecting the thickness of the organic layers or by placing a transparent optical spacer between the electrodes. For example, an OLED device of this invention can have ITO spacer layer placed between a reflective anode and the organic EL media, with a semitransparent cathode over the organic EL media.

The entire contents of the patents and other publications referred to in this specification are incorporated herein by reference.

### EXAMPLES

### Example 1 (Control)

An OLED device with the structure depicted in FIG. 1 was prepared with the organic EL element layers between the electrodes vacuum deposited by standard techniques. The glass (1143 microns) substrate 101 and Indium Tin Oxide (ITO 100 nm) anode 103 had a replicated pattern geometry divided into four similar quadrants. Subsequently deposited onto this anode structure were: a nominally 50 nm NPB hole-transporting layer 107, a 50 nm light-emitting layer 109 containing TBADN (Tert-Butyl-anthracene di-naphthylene) co-doped with 1 weight % TBP (2,5,8,11 tetra-t-butylperylene) w.r.t. TBADN and 2 weight % NPB (N,N′-di(naphthalene-1-yl)-N,N′-diphenyl-benzidine, a hole-transport material) w.r.t. TBADN, a 37.5 nm ALQ electron- transporting layer 111 and finally a 220 nm thick Mg:Ag cathode 113, and the structure packaged as a functional electroluminescent device.

### Example 2 (Invention)

An OLED device was fabricated similarly as in Example 1, with the exception that the organic material light-emitting layer 109 comprising TBADN and co-dopants TBP and NPB was deposited by a method in accordance with the present invention under atmospheric conditions. More particularly, a SAS type particle generation process of the type disclosed in copending, commonly assigned U.S. Ser. No. 10/814,354 (Docket 86430) was employed to generate a desired gaseous flow stream. A nominally 1800 ml stainless steel particle formation vessel was fitted with a 4 cm diameter agitator of the type disclosed in U.S. Pat. No. 6,422,736, comprising a draft tube and bottom and top impellers. CO₂ was added to the particle formation vessel while adjusting temperature to 90 C. and pressure to 300 Bar and while stirring at 2775 revolutions per minute. The addition of CO₂ at 100 g/min through a feed port that had a 200 μm orifice at its tip, and a 0.1 wt % solution of TBADN co-doped with 1 weight % TBP (w.r.t. TBADN) and 2 weight % NPB (w.r.t. TBADN) in acetone at 5 g/min, through a 100 μm tip, was then commenced and the process was allowed to reach a steady state. The CO₂ and solution feed ports were located close to the bottom impeller as disclosed for the inlet tubes for the mixer, such that both the solution and the CO₂ feed streams were introduced into a highly agitated zone within one impeller diameter of the bottom impeller. As disclosed in U.S. Ser. No. 10/814,354, such process has been found to typically result in formation of particles having sizes less than 10 nm.

The outlet port of the particle formation vessel was connected to a first backpressure regulator. A stainless steel pre-filter, whose nominal filtration efficiency for 0.5 μm particles was 90%, was placed upstream of the first backpressure regulator. The output of the first regulator was connected to a compressed flow heater that heated the flow to 90 C. before sending it forward to a second backpressure regulator, where it expanded to a pressure of less than 2 Bar. The flow then passed through an annular heat exchanger that had a central core and an outer annular spiral passageway surrounding the central core through which the flow passed. The heat exchanger was directly in communication with a stainless steel slot placed downstream of the heat exchanger. The slot was 203 gm wide and 2.54 cm long. The mean temperature of the gaseous flow exiting the slot under ambient pressure for the duration of the experiment was 250 C. The coating station substrate was kept 7.62 mm away from the slot. The coating station substrate could be moved back and forth under the slot at predetermined speed. The flow of exhausted material moved nominally parallel to the coating station substrate after the impingement and then went to a vent that had a low level of suction (less than 5 torr below ambient) to aid the flow.

After the system reached steady state conditions of temperature and pressure, a glass slide substrate having an Indium Tin Oxide (ITO 100 nm) anode with the same replicated pattern geometry divided into four similar quadrants as in Example 1 and a 50 nm NPB hole-transporting layer (deposited via a conventional vacuum deposition method) was placed on the coating station surface as the coating substrate. A light-emitting layer was formed by passing the slide under the coating slot back and forth 60 times at a speed of 12.7 mm/sec, while keeping the underside of the slide at a temperature of 5 deg C. The resultant coated structure was then temporarily stored in a dessicator and then subsequently introduced into a vacuum coating chamber, where the remaining electron transporting layer (ALQ at 37.5 nm) and Mg:Ag cathode were deposited as in the control Example 1.

In Table 1 below we note the comparison between the vacuum and inventive deposited OLED cell efficiencies (lumens/watt) and their reproducability as determined by the coefficient of variation (the standard deviation divided by the mean) for the four repeated quadrant patterns.

TABLE I

| | OLED Cell Efficiency | OLED Cell Efficiency |
|---|---|---|
| | lm/W (Control) | lm/W (Invention) |
| Quadrant 1 | 0.728 | 0.746 |
| Quadrant 2 | 0.697 | 0.794 |
| Quadrant 3 | 0.678 | 0.744 |
| Quadrant 4 | 0.747 | 0.737 |
| Mean | 0.712 | 0.755 |
| Coefficient of Variation | 4.37% | 3.48% |

The cell produced by the present invention is not only more efficient than the standard vacuum produced control, but its variability is also less.

The invention has been described in detail with particular reference to certain preferred embodiments thereof, but it will be understood that variations and modifications can be effected within the spirit and scope of the invention.

### PARTS LIST

101 Substrate

103 Anode

107 Hole-Transporting layer (HTL)

109 Light-Emitting layer (LEL)

111 Electron-Transporting layer (ETL)

113 Cathode

250 Current/Voltage source

260 Electrical conductors

1. A process for forming an organic electroluminescent device comprising depositing on a substrate at least first and second electrode layers and an organic EL element comprising one or more organic material layers between the first and second electrode layers, wherein at least one organic material layer of the EL element is deposited by
(i) providing a continuous stream of amorphous solid particles of organic material suspended in at least one carrier gas, the solid particles having a volume-weighted mean particle diameter of less than 500 nm, at an average stream temperature below the glass transition temperature of the solid particles of organic material,
(ii) passing the stream provided in (i) into a heating zone, and heating the stream in the heating zone to elevate the average stream temperature to above the glass transition temperature of the solid particles of organic material, wherein no substantial chemical transformation of the organic material occurs due to heating of the organic material,
(iii) exhausting the heated stream from the heating zone through at least one distributing passage, at a rate substantially equal to its rate of addition to the heating zone in step (ii), wherein the carrier gas does not undergo a thermodynamic phase change upon passage through the heating zone and distribution passage, and
(iv) maintaining the substrate at a temperature below the temperature of the heated stream while exposing the substrate to the exhausted flow of the heated stream to deposit particles of the organic material to form a thin uniform layer of the organic material on the substrate surface.

2. A process according to claim 1, wherein the continuous stream of solid particles of organic material suspended in at least one carrier gas is generated by a supercritical fluid based process.

3. A process according to claim 2, wherein a supercritical fluid is employed as an anti-solvent in the supercritical fluid based process, and the continuous stream of particles of organic material suspended in at least one carrier gas passed into a heating zone in (ii) is prepared under essentially steady state conditions by precipitation of the organic substance from a solution upon contact with the supercritical fluid antisolvent in a particle formation vessel and exhaustion of the particle and supercritical fluid from the vessel through an expansion nozzle.

4. A process according to claim 3, wherein supercritical fluid contains at least carbon dioxide.

5. A process according to claim 4, where the uniform layer deposited in step (iv) is a continuous film having a thickness of less than 1 micrometer.

6. A process according to claim 5, where the continuous film is amorphous.

7. A process according to claim 6, where the at least one organic material layer is deposited on the surface of a previously deposited organic material layer, and the deposited amorphous film has long-range order.

8. A process according to claim 1 in which the film is deposited at ambient or near ambient conditions of pressure.

9. A process according to claim 1, wherein the substrate is moved in relation to the exhausted flow of the heated stream to form the thin uniform layer of the organic material.

10. A process according to claim 1 where the at least one organic material layer is an electroluminescent light emissive layer.

11. A process according to claim 10 in which the light emissive layer comprises a dopant that fluoresces from an excited singlet spin state or that phosphoresces from an excited triplet spin state.

12. An organic electroluminescent device comprising at least first and second electrode layers and an organic EL element comprising one or more organic material layers between the first and second electrode layers deposited on a substrate, wherein at least one organic material layer of the EL element is deposited according to claim 1.

13. A device according to claim 12, where the at least one organic material layer is a continuous film having a thickness of less than 1 micrometer.

14. A device according to claim 13, where the continuous film is amorphous.

15. A device according to claim 14, where the at least one organic material layer is deposited on the surface of a previously deposited organic material layer, and the deposited amorphous film has long-range order.

16. A device according to claim 12 where the at least one organic material layer is an electroluminescent light emissive layer.

17. A device according to claim 16 where the light emissive layer emits in the blue portion of the visible light spectrum from 430 nm to 510 nm.

18. A device according to claim 16 in which the spatial inhomogeniety of the luminescent intensity of the light emissive layer over an area of 1.6 cm² is less than 4%.

19. A device according to claim 16 where the luminescent efficiency of the light emissive layer is at least 0.7 lm/w.

20. A device according to claim 16 in which the light emissive layer comprises a dopant that fluoresces from an excited singlet spin state or that phosphoresces from an excited triplet spin state.
